(19) United States
(12) Patent Application Publication
(10) Pub. No.: US 2010/0159635 A1
(43) Pub. Date: Jun. 24, 2010

(54) METHOD OF PATTERNING CONDUCTIVE LAYER AND DEVICES MADE THEREBY

(75) Inventor: Viorel Olariu, Colorado Springs, CO (US)

Correspondence Address: WEYERHAEUSER COMPANY;INTELLECTUAL PROPERTY DEPT., CH 1J27, P.O. BOX 9777, FEDERAL WAY, WA, 98063, US

(73) Assignee: WEYERHAEUSER COMPANY, Federal Way, WA (US)

(21) Appl. No.: 12/343,874

(22) Filed: Dec. 24, 2008

(51) Int. Cl. H01L 21/768; H01L 51/10; H01L 51/40

(52) U.S. Cl. 438/99; 438/608; 438/660; 438/197; 257/E51.005; 257/E21.575

(57) ABSTRACT

Methods for patterning a conductor through oxidation are provided. Devices fabricated using the method include organic transistors having a gate electrode and dielectric layer patterned by the method, source and drain electrodes, and an organic semiconducting layer.

### BACKGROUND

Organic semiconductor materials have been targeted as the active component of semiconductor devices, such as organic thin-film transistors (OTFT) devices. OTFTs have now been integrated into device systems as replacements for single crystal, polycrystalline, and amorphous silicon. While the performance of OTFTs cannot currently match the performance of single crystal silicon transistors, the performance of the best OTFT devices currently known are comparable to amorphous silicon devices. While the performance of OTFTs does not, in itself, provide an advantage over traditional semiconductor materials (e.g., silicon), the potential for OTFTs to be manufactured on flexible substrates (such as polymers) and to be fabricated using liquid-based processes (such as inkjet printing) lead to the potential for low cost, high volume production of OTFT devices. Particular uses targeted for OTFTs include organic electroluminescent displays, smart cards, plastic computer chips, and radio frequency identification (RFID) tags.

Current manufacturing techniques for OTFT devices include traditional semiconductor processing techniques (e.g., lithography, etching, and film deposition techniques), as well as inkjet printing and hybrids of both traditional and non-traditional fabrication methods.

The preferred fabrication method for an OTFT device is determined by the requirements for the device, such as cost, performance, and materials considerations. A flexible OTFT device may be fabricated using inexpensive materials, such as plastics or cardboard, as substrates, and inkjet-printed layers that reduce the cost of fabrication by avoiding traditional semiconductor processing techniques. Such flexible OTFT devices are desirable for their flexibility and inexpensive fabrication; however, their performance in some ways may be less strong in relation to devices fabricated using more rigid substrates (e.g., silicon wafers) and traditional semiconductor processing techniques.

OTFT devices fabricated using both inorganic and organic materials may provide a compromise between cost, flexibility, and performance. For example, a popular OTFT configuration uses highly-doped silicon as a gate electrode and silicon dioxide as an insulator; however, while such devices have the potential for relatively high performance, they are not flexible. Attempts have been made to integrate inorganic materials into flexible semiconductor devices, such as OTFT devices, but new techniques must still be developed for this nascent field to assist manufacturers of semiconductor devices in forming high-performing, flexible, and inexpensive devices.

### SUMMARY

Methods for patterning a conductor by oxidation are provided, as well as devices formed using the methods.

In one aspect, a method for forming a patterned aluminum layer on a substrate is provided. In one embodiment, the method includes the steps of providing an aluminum layer on a substrate; oxidizing a portion of the aluminum layer to provide an aluminum oxide layer and a residual aluminum layer, the aluminum oxide layer being disposed over the residual aluminum layer; forming a patterned resist layer over the aluminum oxide layer, where a portion of the aluminum oxide layer is exposed through the patterned resist layer; and oxidizing a portion of the residual aluminum layer that is beneath the portion of the aluminum oxide layer exposed through the patterned resist layer to provide a patterned aluminum layer substantially covered by aluminum oxide.

In another aspect, a method is provided for forming a patterned conductive layer on a substrate. In one embodiment, the method includes the steps of providing a conductive layer on a substrate; oxidizing a portion of the conductive layer to provide a dielectric layer and a residual conductive layer, the dielectric layer being disposed over the residual conductive layer; forming a patterned resist layer over the dielectric layer, where a portion of the dielectric layer is exposed through the patterned resist layer; and oxidizing a portion of the residual conductive layer that is beneath the portion of the dielectric layer exposed through the patterned resist layer to provide a patterned conductive layer substantially covered by dielectric.

In another aspect, a method for fabricating a transistor is provided. In one embodiment, the method includes the steps of providing an aluminum layer on a substrate; oxidizing a portion of the aluminum layer to provide an aluminum oxide layer and a residual aluminum layer, the aluminum oxide layer being disposed over the residual aluminum layer; forming a patterned resist layer over the aluminum oxide layer, where a portion of the aluminum oxide layer is exposed through the patterned resist layer; oxidizing a portion of the residual aluminum layer that is beneath the portion of the aluminum oxide layer exposed through the patterned resist layer to provide a patterned aluminum layer substantially covered by aluminum oxide, where the patterned aluminum layer comprises a gate electrode covered at least in part by the aluminum oxide layer; forming a source electrode and a drain electrode disposed on the aluminum oxide layer; and forming a semiconductor layer at least intermediate the source electrode and the drain electrode and on the aluminum oxide layer.

### DESCRIPTION OF THE DRAWINGS

The foregoing aspects and many of the attendant advantages of the subject matter described herein will become more readily appreciated as the same become better understood by reference to the following detailed description, when taken in conjunction with the accompanying drawings, wherein:

FIG. 1 is a block diagram representing a process flow of a representative method for manufacturing a patterned conductive layer substantially covered by dielectric in accordance with the embodiments described herein; and

FIGS. 2A-2F are cross-sectional illustrations of the stages of fabricating an organic thin-Film transistor in accordance with the embodiments described herein.

### DETAILED DESCRIPTION

Methods for patterning a conductor by oxidation are provided, as well as devices formed using the methods. Representative devices include hybrid inorganic-organic OTFT devices having metal gate electrodes patterned using the methods and organic semiconducting layers. Various embodiments of these methods and devices will now be described. The following description provides specific details for a thorough understanding of, and enabling description for, these embodiments. However, one skilled in the art will understand that the embodiments may be practiced without these details. Well-known structures and functions have not been shown or described to avoid unnecessarily obscuring the descriptions of the embodiments disclosed herein.

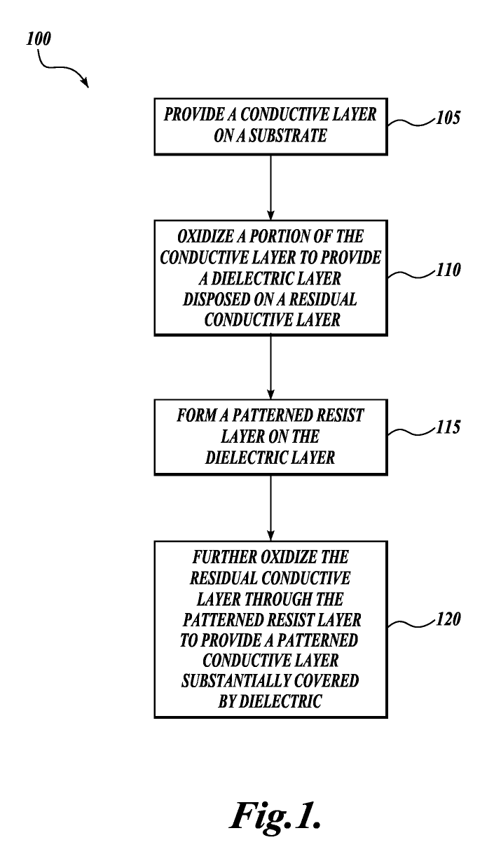

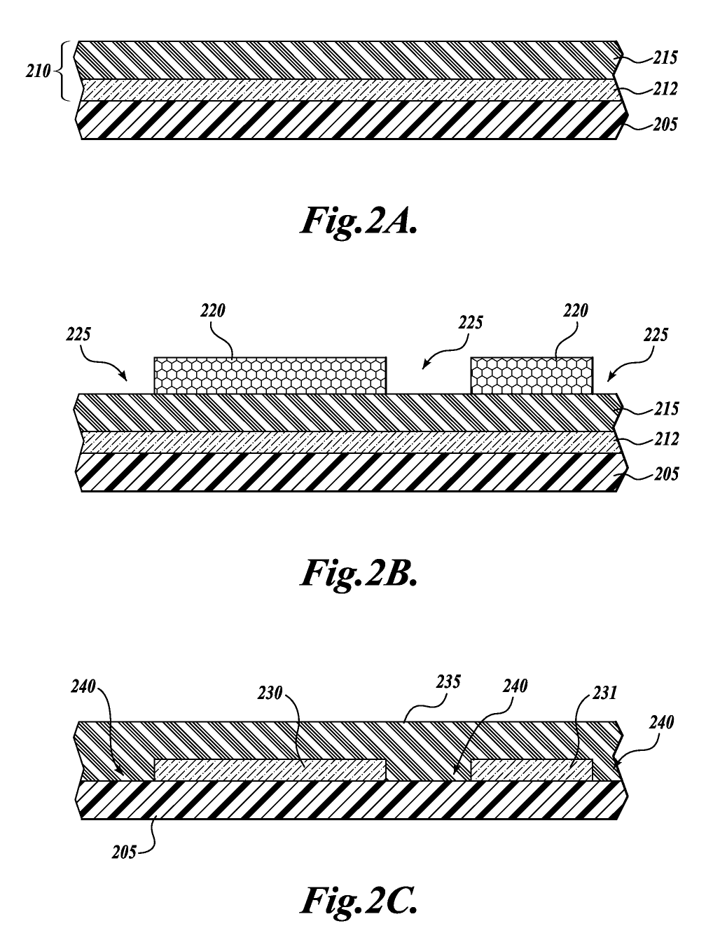

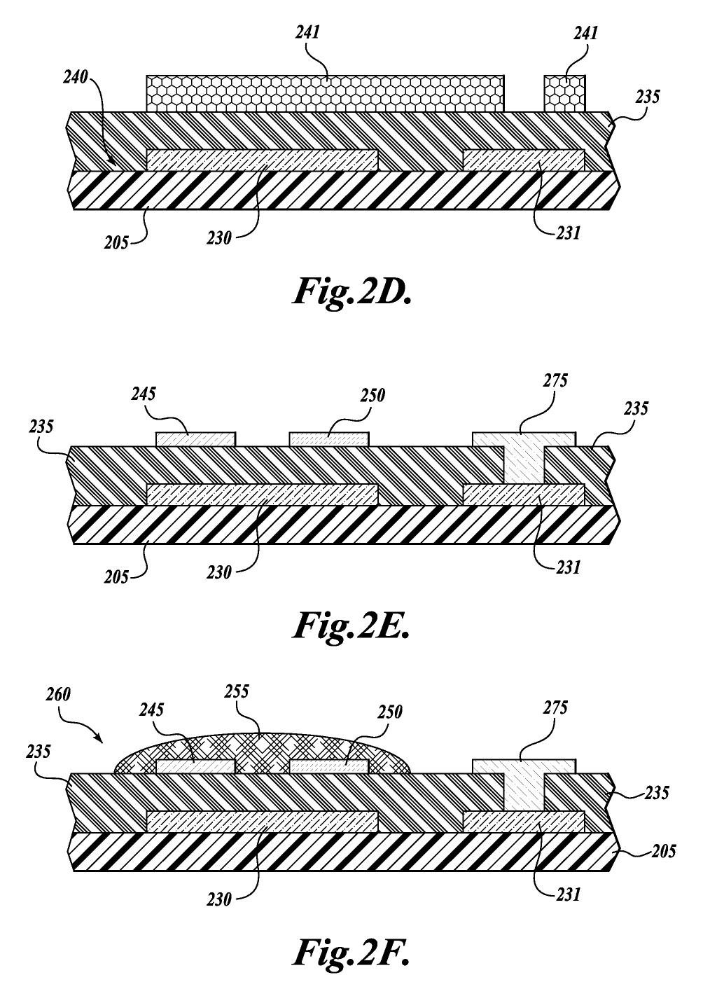

The embodiments provided will now be described with reference to FIGS. 1 and 2A-2F. Referring to FIG. 1, a method 100 for forming a patterned conductive layer substantially covered by dielectric is illustrated by a flow chart. The method 100 is particularly useful for fabricating devices having a conductor-insulator interface, such as an organic thin-film transistor (OTFT), as will be described in more detail below.

The method 100 begins with a step 105 of providing a conductive layer on a substrate. The substrate can be any substrate known to those of skill in the art and includes semiconductors and insulators, including polymers. The substrate can be flexible or rigid depending on the requirements of the finished device. If a flexible OTFT device is desired, a flexible substrate is preferred. Representative flexible substrates include cardboard and polymers, such as polyethylene terephthalate (PET), polyethylene naphthalate (PEN), polytetrafluoroethylene (PTFE), and nylon.

The conductive layer is a conducting material capable of being converted to a dielectric material through oxidation. Representative conducting materials include aluminum, silver, and zinc. A preferred representative conductive material is aluminum, which can be oxidized into aluminum oxide (e.g., Al₂O₃).

The method 100 continues with a step 110 of oxidizing a portion of the conductive layer to provide a dielectric layer disposed on a residual conductive layer that is not oxidized. Oxidation of the conductive material can be accomplished by techniques, such as heating, exposure to gas, exposure to water vapor, plasma techniques, combinations thereof, and other techniques known to those of skill in the art. An exemplary method for oxidizing a portion of the conductive layer is to subject the conductive layer to a direct current oxygen plasma.

In one embodiment, the substrate is a polymer having an aluminum conductive layer deposited thereon. As noted above, the aluminum conductive layer is partially oxidized to form an aluminum oxide dielectric layer on the upper (exposed to the environment) surface of the conductive layer and an underlying residual conductive aluminum layer that is not oxidized.

It will be appreciated that the entire surface of the substrate need not be covered with the conductive layer, and all of the conductive layer need not be oxidized.

The method 100 continues with a step 115 of forming a patterned resist layer on the dielectric layer. Forming a patterned resist layer is a technique known to those of skill in the art and can include the lithographic (e.g., photolithography or soft lithography) definition of a pattern in a resist film that results in portions of the dielectric layer being covered by the resist, and portions of the dielectric layer exposed (i.e., not covered by the resist) such that the two different portions of the surface (covered and uncovered by resist) can be processed differently.

Resist materials are generally known to those of skill in the art and a representative resist is a polymer. In a representative embodiment, the resist used in the method 100 resists deterioration under the conditions used to oxidize the residual conductive layer as described in the following paragraphs and is capable of shielding the dielectric and conductive layers beneath it from oxidation.

The method 100 is completed by a step 120 of oxidizing the residual conductive layer that lies beneath the portions of the dielectric layer exposed through the patterned resist layer. In the representative embodiment of the method 100 described herein where the conductive layer is aluminum, the residual aluminum conductive layer is further oxidized where photoresist is not present on the surface of the dielectric. The oxidation of the residual conductive layer proceeds through the already-formed dielectric layer to thicken the dielectric layer in those areas where photoresist does not protect the residual conductive layer. In a preferred embodiment, the unprotected area of the conductive layer that is further oxidized is fully oxidized such that the entire thickness of the residual conductive layer is oxidized, thus providing insulation between areas of the residual conductive layer that were protected by the photoresist and, thus, remain as conductive material (e.g., aluminum).

The method 100 described in FIG. 1 is useful for forming devices that utilize a conductor-dielectric interface as a portion of the device. A representative example of such a device is a transistor. Representative transistors include both inorganic (e.g., silicon) and organic (e.g., pentacene) semiconducting layers. In a preferred embodiment, an OTFT device is formed. The fabrication of an OTFT using the method, as illustrated in FIG. 1, will now be described in more detail with reference to FIGS. 2A-2F.

Referring now to FIG. 2A, a substrate 205 having an upper surface and an opposing bottom surface is illustrated. Adjacent to the upper surface of substrate 205 is a conductive layer 210 that has been partially oxidized to provide a dielectric layer 215 and a residual conductive layer 212.

Referring now to FIG. 2B, patterned resist 220 is formed on dielectric layer 215. Patterned resist 220 can be formed using conventional techniques, such as photolithography. The resist 220 covers portions of the dielectric layer 215 and residual conductive layer 212. Where the resist is not present (i.e., where lithography and post-processing have removed the resist 220), vacancies 225 exist in the patterned resist 220, thus exposing the dielectric layer 215 and residual conductive layer 212 to further processing.

Referring now to FIG. 2C, portions of dielectric layer 215 and residual conductive layer 212 not covered by patterned resist 220 have been further exposed to an oxidation source such that the residual conductive layer 212 has been oxidized fully through its thickness down to substrate 205. Patterned resist 220 has been removed post-oxidation to yield the structure illustrated in FIG. 2C having patterned conductive features 230 and 231 substantially covered by a patterned dielectric 235 that includes thick dielectric portions 240 where the dielectric extends entirely to the substrate 205.

In the embodiment described herein with reference to FIGS. 2A-2F, where the end product of the processing method is an OTFT, the patterned conductive feature 230 is the gate of the OTFT, the patterned conductive feature 231 is an interconnect for connecting together devices in an integrated circuit, and the patterned dielectric 235 is the dielectric layer insulating the conductive features 230 and 231 and acting as the gate dielectric of the OTFT. The thick dielectric portions 240 that extend to the substrate 205 act to laterally insulate the conductive features 230 and 231 (e.g., from neighboring devices).

Additional processing of the patterned dielectric layer 235 is contemplated, as is illustrated in FIG. 2D. Referring now to FIG. 2D, a via mask 241 is formed in resist on the patterned dielectric 235 (e.g., by photolithography). In the illustrated exemplary embodiment, the patterned dielectric 235 is etched through to the conductive feature 231 (e.g., an interconnect). The resist used to form the via mask 241 can be the same or different from the resist used to form the patterned resist 220 layer described above. As illustrated in FIG. 2E, a via 275 is formed by depositing a conductive material over the interconnect 231.

The description of the fabrication of an OTFT continues with reference to FIG. 2E, where electrodes 245 and 250 are patterned on the upper surface of patterned dielectric layer 235. The electrodes 245 and 250 include, in this representative OTFT example, a source electrode 245 and a drain electrode 250.

The source electrode 245 and drain electrode 250 can be fabricated from materials known to those of skill in the art, including metals, such as gold or silver, or organic materials, such as conductive polymers. The processing techniques for depositing the source electrode 245 and drain electrode 250 are known to those of skill in the art and include traditional semiconductor processing techniques (particularly if metals are used) and liquid-based techniques, such as inkjet printing (particularly if organic conductors are used).

Referring to FIG. 2F, an OTFT device 260 is formed by the deposition of an organic semiconducting layer 255 intermediate the source electrode 245 and drain electrode 250 and upon the patterned dielectric layer 235. The organic semiconducting layer 255 can be deposited using techniques known to those of skill in the art. In a representative embodiment, the organic semiconducting layer 255 is deposited using a liquid-based technique, such as inkjet printing, which can facilitate the inexpensive and efficient production of OTFT devices.

Materials useful for forming the organic semiconducting layer 255 include organic semiconductors known to those of skill in the art. Representative organic semiconductor materials include polymers, such as polythiophenes, and small organic molecules, such as pentacene.

While not illustrated in the figures herein, it will be appreciated that an encapsulation layer can be applied to a completed OTFT device 260 using materials and methods known to those of skill in the art.

As described above with reference to FIGS. 2A-2F, the fabrication of interconnects 231 and vias 275 using the methods disclosed herein is possible. Interconnects are useful for connecting together components in an integrated circuit. In a representative example, an OTFT 260 is integrated into an RFID circuit (not illustrated) by interconnects 231 at least partially defined using the method. Such an OTFT-based RFID circuit can be fabricated with both OTFTs 260 and interconnects 231 fabricated using the method.

A preferred embodiment of an OTFT device 260 fabricated using the method includes a polymer substrate 205; an aluminum conducting layer 210 that is selectively oxidized, as described herein, to form a gate electrode 230; an aluminum oxide patterned dielectric layer 235; metallic (e.g., gold or silver) source electrode 245 and drain electrode 250; and a polymeric or small organic molecule semiconducting layer 255. While the OTFT device 260 described in this embodiment includes organic (e.g., semiconducting layer 255) and inorganic (e.g., aluminum gate electrode 230 and aluminum oxide dielectric layer 235) materials, the final device 260 may still be flexible when the layers of the device are thin enough to allow flexibility and the substrate 205 is flexible.

The representative OTFT device 260 described herein is operated using methods known to those of skill in the art. The device 260 can be integrated into any electrical system as a replacement for a traditional transistor device (e.g., MOSET). In an exemplary embodiment, the device 260 is integrated into an RFID tag. If the device 260 and other components of the RFID tag are manufactured from flexible materials, the entire RFID tag will be flexible.

The methods disclosed herein are especially useful for manufacturing high-volume, low-cost, potentially-disposable electronics, such as RFID tags, electronic newspapers, electronic toys, disposable notepads, etc. In the representative example of RFID tags, the methods disclosed here have further advantages because an antenna can be integrated with other electronic components (e.g., OTFTs) using the methods.

While the embodiments disclosed above have referenced organic semiconductor materials for use as a semiconductor material, it is understood that semiconductor materials other than organic semiconductor materials can be used to provide the above described semiconducting layer.

While illustrative embodiments have been illustrated and described, it will be appreciated that various changes can be made therein without departing from the spirit and scope of the invention. Aspects of the disclosure described in the context of particular embodiments may be combined or eliminated in other embodiments.

Further, while advantages associated with certain embodiments of the disclosure may have been described in the context of those embodiments, other embodiments may also exhibit such advantages, and not all embodiments need necessarily exhibit such advantages to fall within the scope of the disclosure. Accordingly, the invention is not limited except as by the appended claims.

We claim:

1. A method for forming a patterned aluminum layer on a substrate comprising:
(a) providing an aluminum layer on a substrate;
(b) oxidizing a portion of the aluminum layer to provide an aluminum oxide layer and a residual aluminum layer, the aluminum oxide layer being disposed over the residual aluminum layer;
(c) forming a patterned resist layer over the aluminum oxide layer, wherein a portion of the aluminum oxide layer is exposed through the patterned resist layer; and
(d) oxidizing a portion of the residual aluminum layer that is beneath the portion of the aluminum oxide layer exposed through the patterned resist layer to provide a patterned aluminum layer substantially covered by aluminum oxide.

2. The method of claim 1 wherein providing an aluminum layer on a substrate comprises depositing aluminum on the substrate using a thin-film technique selected from the group consisting of electron beam deposition and sputtering.

3. The method of claim 1 wherein the substrate comprises a flexible substrate.

4. The method of claim 1 wherein oxidizing a portion of the aluminum layer and oxidizing the residual aluminum layer comprise an oxidation method independently selected from the group consisting of thermal oxidation and plasma oxidation.

5. The method of claim 1, further comprising forming an organic semiconductor layer over the patterned aluminum layer substantially covered by aluminum oxide.

6. The method of claim 1, wherein the patterned aluminum layer includes at least one feature selected from the group consisting of an organic thin film transistor gate electrode and an interconnect.

7. A method for forming a patterned conductive layer on a substrate comprising:
(a) providing a conductive layer on a substrate;
(b) oxidizing a portion of the conductive layer to provide a dielectric layer and a residual conductive layer, the dielectric layer being disposed over the residual conductive layer;
(c) forming a patterned resist layer over the dielectric layer, wherein a portion of the dielectric layer is exposed through the patterned resist layer; and
(d) oxidizing a portion of the residual conductive layer that is beneath the portion of the dielectric layer exposed through the patterned resist layer to provide a patterned conductive layer substantially covered by dielectric.

8. The method of claim 7 wherein the conductive layer is selected from the group consisting of aluminum, silver, and zinc.

9. The method of claim 7 wherein the substrate comprises a flexible substrate.

10. The method of claim 7 wherein oxidizing a portion of the conductive layer and oxidizing the residual conductive layer comprise an oxidation method independently selected from the group consisting of thermal oxidation and plasma oxidation.

11. The method of claim 7, further comprising forming an organic semiconductor layer over the patterned conductive layer substantially covered by dielectric.

12. The method of claim 7 wherein the patterned conductive layer includes at least one feature selected from the group consisting of an organic thin film transistor gate electrode and an interconnect.

13. A method for fabricating a transistor comprising:
(a) providing an aluminum layer on a substrate;
(b) oxidizing a portion of the aluminum layer to provide an aluminum oxide layer and a residual aluminum layer, the aluminum oxide layer being disposed over the residual aluminum layer;
(c) forming a patterned resist layer over the aluminum oxide layer, wherein a portion of the aluminum oxide layer is exposed through the patterned resist layer;
(d) oxidizing a portion of the residual aluminum layer that is beneath the portion of the aluminum oxide layer exposed through the patterned resist layer to provide a patterned aluminum layer substantially covered by aluminum oxide, wherein the patterned aluminum layer comprises a gate electrode covered at least in part by the aluminum oxide layer;
(e) forming a source electrode and a drain electrode on the aluminum oxide layer; and
(f) forming a semiconductor layer at least intermediate the source electrode and the drain electrode and on the aluminum oxide layer.

14. The method of claim 13 wherein the source electrode and drain electrode are a material independently selected from the group consisting of a metal and an organic conductor.

15. The method of claim 13 wherein forming a source electrode and a drain electrode are independently selected from the group consisting of metal deposition methods and inkjet printing.

16. The method of claim 13 wherein forming a semiconductor layer comprises forming an organic semiconductor layer.

17. The method of claim 13 wherein the patterned aluminum layer further comprises at least one interconnect.

18. The method of claim 13 wherein the substrate comprises a flexible substrate.

19. The method of claim 13 wherein oxidizing a portion of the aluminum layer and oxidizing the residual aluminum layer comprise an oxidation method independently selected from the group consisting of thermal oxidation and plasma oxidation.

20. The method of claim 13, further comprising forming an encapsulation layer covering the source electrode, drain electrode, and semiconductor layer.
